(19) United States
(12) Patent Application Publication
(10) Pub. No.: US 2023/0216272 A1
(43) Pub. Date: Jul. 6, 2023

(54) METHOD AND DEVICE FOR GENERATING A LASER PULSE

(71) Applicant: LASER ZENTRUM HANNOVER E.V., Hannover (DE)

(72) Inventor: Stefan SPIEKERMANN, Hannover (DE)

(21) Appl. No.: 18/000,874

(22) PCT Filed: Jun. 8, 2021
(86) PCT No.: PCT/EP2021/065289

§ 371 Date: Dec. 6, 2022

(30) Foreign Application Priority Data
Jun. 8, 2020 (DE) 10 2020 115 133.0

(51) Int. Cl. H01S 5/04; H01S 5/20; H01S 5/34; H01S 5/062

(52) U.S. Cl. CPC H01S 5/041; H01S 5/2036; H01S 5/3415; H01S 5/06216

(57) ABSTRACT

The invention relates to a method for generating a laser pulse, wherein during the method a first semi-conductor laser in the form of a broadband laser diode is used to generate a pump laser pulse, the pump laser pulse is used to pump a second semi-conductor laser, the laser pulse being shorter than the pump laser pulse and the second semi-conductor laser comprising at least 20 quantum wells arranged above one another in the emission direction of the laser pulse.

The invention relates to a method for generating a laser pulse as well as a device for conducting such a method.

In industrial applications, ultra short pulse lasers are used particularly in the field of material processing, but also in many other fields of technical application. Depending on the application, they are used to generate laser pulses with a pulse length of less than 50 ps, preferably less than 10 ps, up to a pulse length of a few fs.

Laser arrangements are known from the prior art which are able to generate this type of laser pulse. A prior-art setup of a 10 ps laser source initially includes a relatively low power injection laser. The laser pulse emitted by said injection laser is fed to a downstream power amplifier. As a result, typical injection lasers emit pulses with an energy some nJ, which can be successively post-amplified to some pJ up to mJ. An injection laser is a semi-conductor laser that comprises multiple layers of different materials arranged on top of one another, wherein the laser radiation exits at the lateral surfaces of the bundle of layers structured in this way, i.e. parallel to the plane of the layers. It can be operated in pulse mode and, in particular, pumped with electrical energy. However, the significant angle of divergence of the emitted laser radiation presents a disadvantage.

Other injection lasers are constructed as mode-locked fiber lasers with dimensions of some 10 cm×10 cm. In addition, expensive fiber components and semi-conductor components are used. The disadvantages of this type of injection laser are the high cost and the large installation space required. Furthermore, the pulse repetition rates for such lasers are free-running in the range of several MHz. However, typical applications require pulse repetition rates in the range below one MHz. To achieve this, the prior art specifically extracts individual pulses from the pulse train using electro-optic and/or acousto-optic modulators, which incur additional costs.

A laser arrangement for generating ultra short laser pulses is known from WO 2008/116357 A1. A first semi-conductor laser is pumped with an electrical energy source. The laser pulses generated in the process are fed to an optical amplifier, which may also be a semi-conductor. These optical amplifiers have been known from the prior art as “semi-conductor optical amplifier” (SOA) for many years. In this arrangement, the pulse length depends on the pulse length that is generated in the first semi-conductor laser.

WO 2010/064238 A1 discloses a laser arrangement in which a dual gain switch is used to generate the laser pulse. In the gain-switching method, the respective laser to be pumped is pumped with an energy pulse of a certain temporal length. Each laser resonator requires a pulse build-up time to emit coherent radiation. If the length of the pump pulse is shorter than the pulse build-up time, the laser emits a pulse whose length is determined solely by the amplification and resonator configuration of the laser. This is used to generate an ultra short pulse that is subsequently optically amplified. Conversely, WO 2010/064238 A1 proposes re-using the first laser pulse emitted by the semi-conductor laser as a pump pulse for a fiber laser. Although this does enable the generation of extremely short pulses, the above-named disadvantages of the fiber laser still remain. Such “cascade gain circuits” are known from the literature, where laser pulses with a length of some ns and a peak power in the range of some kW could be generated.

The invention aims to propose a method and a device with which ultra short laser pulses can be simply and cost-effectively generated, without requiring much installation space.

The invention solves the addressed task by way of a method for generating a laser pulse, wherein during the method a first semi-conductor laser in the form of a broad-band laser diode is used to generate a pump laser pulse and the pump laser pulse is used to pump a second semi-conductor laser, the laser pulse being shorter than the pump laser pulse and the second semi-conductor laser comprising at least 20 quantum wells arranged on top of one another in the emission direction of the laser pulse. The length of the laser pulse is preferably less than 80% the length of the pump laser pulse.

In this method, a broadband laser diode that forms the first semi-conductor laser is preferably first electrically pumped. An electrical energy pulse is used so that the broadband laser diode is gain switched. For this purpose, it is advantageous for the pumping process to be completed before the emission process, i.e. the pulse build-up time of the broadband laser diode is longer than the length of the electrical pump pulse. This should prevent subsequent pulses. At the same time, the pulse build-up time must not be so long that the free charge carriers generated by the electrical pump pulse disappear again by recombination and the laser pulse is therefore not generated.

The pump pulse generated in this way, which is emitted by the broadband laser diode, is used as a pump pulse for the second semi-conductor laser. It comprises quantum wells in which the free charge carriers required are generated by the pump pulse. The number of quantum wells is decisive for the pulse build-up time, among other things. Preferably, a surface-emitting optically pumped semiconductor laser (OPSL) is used. This emits the laser radiation perpendicular to the plane of the individual layers. The second semi-conductor laser used in the method according to the invention features at least 20 quantum wells, which are arranged on top of each other in the emission direction. By increasing the number of quantum wells compared to conventional OPSLs, the storable energy and thus the gain is increased, so that the pulse build-up time is reduced and a pulse is emitted before the stored energy is lost through recombination. This means that, on the one hand, the pulse build-up time is larger than the length of the pump laser pulse and, on the other hand, is small enough to enable the lasering of the second semi-conductor.

The second semi-conductor preferably features at least 50, preferably at least 75, especially preferably at least 100 quantum wells, which are arranged on top of each other in the emission direction. This increases the energy of the generated laser pulses. However, the pulse build-up time is reduced at the same time. It may therefore be advantageous or even necessary to additionally increase the pulse build-up time in another way, for example by extending the resonator of the second semi-conductor laser.

In a preferred embodiment, multiple—preferably two or three—quantum wells are arranged so close together in the second semi-conductor laser that they are within an interference well of the standing wave that builds up in the resonator. One can also refer to multiple quantum wells, particularly double quantum wells or triple quantum wells. Particularly preferably, several, preferably at least 20, especially preferably at least 50, of these multiple quantum wells are arranged on top of each other in the emission direction. By using such multiple quantum wells, more quantum wells can be accommodated in a small space. This is advantageous because the standing wave of the pump radiation emitted by the broadband laser diode and the standing wave of the gain-switched second semi-conductor laser run out of phase. This is prevented or at least mitigated the smaller the distance between the quantum wells. In addition, it is advantageous for the quality of semi-conductor epitaxy to make the entire layer structure as thin as possible.

Preferably, the first semi-conductor laser is electrically pumped.

Advantageously, the pump laser pulse is shorter than 250 ps, preferably shorter than 150 ps, especially preferably shorter or equal to 100 ps.

The first semi-conductor laser is preferably selected such that the pump laser pulse is shorter than the pulse build-up time of the second semi-conductor laser. In a preferred embodiment, the second semi-conductor laser is pumped by means of so-called “in-well pumping”. In this process, the energy of the pump laser pulse is radiated straight into the quantum wells and is immediately available there. The wave-length of the pump light is preferably approximately 50 nm below that of the laser pulse. For example, the pump laser pulse is emitted with a wavelength of 980 nm and the wavelength of the laser pulse is 1030 nm. As an alternative, so-called “barrier pumping” can be used, with which the pump energy is not radiated straight into the quantum wells, but into barriers, i.e. semi-conductor layers adjacent to the quantum wells. These layers are usually thicker than those of the quantum wells, thereby enabling higher absorption efficiencies. However, energy absorbed in the barriers is not immediately available to the quantum wells. In this case, the wavelength of the pump radiation is preferably approximately 180 nm below that of the laser pulse. “In-well pumping” is advantageous for the generation of the shortest possible pulses.

Advantageously, the generated laser pulse is shorter than 50 ps, preferably shorter than 25 ps, especially preferably shorter or equal to 10 ps.

The invention also solves the addressed task by way of a device for generating a laser pulse, the device comprising a first semi-conductor laser in the form of a broad-band laser diode and a second semi-conductor laser with at least 20 quantum wells arranged on top of each other in the emission direction of the laser pulse, and being configured to conduct a method described here. Preferably, the second semi-conductor laser features a resonator, the length of which is designed in such a way that the pulse build-up time of the second semi-conductor laser is longer than the pump laser pulse. Here, the pump laser pulse is the laser pulse emitted by the first semi-conductor laser when a method as described here is conducted. The device preferably features at least one power amplifier that is configured and arranged to amplify the laser pulse.

1. A method for generating a laser pulse, comprising:
using a first semi-conductor laser in a form of a broad-stripe laser diode to generate a pump laser pulse, wherein the laser pulse to be generated is shorter than the pump laser pulse, and
wherein the pump laser pulse is used to pump a second semi-conductor laser comprising at least 20 quantum wells arranged on top of each other in an emission direction of the laser pulse, and
emitting the laser pulse from the second semi-conductor laser.

2. The method according to claim 1, wherein the second semi-conductor laser comprises at least 50 quantum wells arranged on top of each other in the emission direction of the laser pulse.

3. The method according to claim 1 wherein the first semi-conductor laser is electrically pumped.

4. The method according to claim 1 wherein the pump laser pulse is shorter than 250 ps.

5. The method according to claim 1 wherein the pump laser pulse generated by the first semi-conductor laser is shorter than the pulse build-up time of the second semi-conductor laser.

6. The method according to claim 1 wherein the laser pulse is shorter than 50 ps.

7. A device for generating a laser pulse, comprising:
a first semi-conductor laser in a form of a broad-stripe laser diode; and
a second semi-conductor laser with at least 20 quantum wells arranged on top of each other in an emission direction of the laser pulse to be emitted by the second semi-conductor laser.

8. The device according to claim 7, wherein the second semi-conductor laser comprises a resonator, wherein the resonator has a length which is designed such that a pulse build-up time of the second semi-conductor laser is longer than 80% of a length of a pump laser pulse produced by the first semi-conductor laser.

9. The device according to claim 7 further comprising at least one power amplifier that is configured and arranged to amplify the laser pulse.
